(19) United States
(12) Patent Application Publication
(10) Pub. No.: US 2016/0133472 A1
(43) Pub. Date: May 12, 2016

(54) METHOD OF MANUFACTURING A SEMICONDUCTOR DEVICE

(71) Applicant: SAMSUNG ELECTRONICS CO., LTD., SUWON-SI (KR)

(72) Inventor: JU-YOUN KIM, SUWON-SI (KR)

(21) Appl. No.: 14/697,258

(22) Filed: Apr. 27, 2015

(30) Foreign Application Priority Data
Nov. 7, 2014 (KR) 10-2014-0154336

(51) Int. Cl. H01L 21/28; H01L 29/66

(52) U.S. Cl. CPC H01L 21/28088; H01L 29/66795; H01L 29/66545

(57) ABSTRACT

A method of manufacturing a semiconductor device includes forming an interlayer insulating layer including a first trench and a second trench on a substrate, forming a lower gate conductive layer along lateral surfaces and a bottom surface of the second trench, forming a first capping conductive layer along lateral surfaces and a bottom surface of the first trench and forming a second capping conductive layer on the lower gate conductive layer, forming a first upper gate conductive layer and a second upper gate conductive layer on the first capping conductive layer and the second capping conductive layer, respectively, forming a first barrier layer and a second barrier layer on the first upper gate conductive layer and the second upper gate conductive layer, respectively, and forming a first metal layer and a second metal layer on the first barrier layer and the second barrier layer, respectively. The first barrier layer and the second barrier layer have a thickness of 40 Å or greater.

### CROSS-REFERENCE TO RELATED APPLICATION

A claim of priority under 35 U.S.C. §119 is made to Korean Patent Application No. 10-2014-0154336 filed on Nov. 7, 2014, in the Korean Intellectual Property Office, the contents of which are herein incorporated by reference in their entirety.

### BACKGROUND

The present inventive concept relates to a method for manufacturing a semiconductor device.

Recently, a metal gate is often used instead of a polysilicon gate in order to improve characteristics of a semiconductor device. The metal gate may be formed using a replacement metal gate process.

In order to increase the density of a semiconductor device, the semiconductor device has been gradually scaled-down. In such a scaled-down semiconductor device, the replacement metal gate process may require multiple cycles of etching, deposition and grinding steps.

### SUMMARY

According to an aspect of the present inventive concept, there is provided a method for manufacturing a semiconductor device, the method including forming an interlayer insulating layer including a first trench and a second trench on a substrate, forming a lower gate conductive layer along lateral surfaces and a bottom surface of the second trench, forming a first capping conductive layer along lateral surfaces and a bottom surface of the first trench and forming a second capping conductive layer on the lower gate conductive layer, forming a first upper gate conductive layer and a second upper gate conductive layer on the first capping conductive layer and the second capping conductive layer, respectively, forming a first barrier layer and a second barrier layer on the first upper gate conductive layer and the second upper gate conductive layer, respectively, and forming a first metal layer and a second metal layer on the first barrier layer and the second barrier layer, respectively, wherein the first barrier layer and the second barrier layer have a thickness of 40 Å or greater.

According to another aspect of the present inventive concept, there is provided a method for manufacturing a semiconductor device, the method including forming a first fin type active pattern and a second fin type active pattern on a substrate, forming a first trench crossing the first fin type active pattern on the first fin type active pattern and forming a second trench crossing the second fin type active pattern on the second fin type active pattern, forming a first TiN layer along lateral surfaces and a bottom surface of the second trench, forming a second TiN layer along lateral surfaces and a bottom surface of the first trench and forming second TiN layer on the first TiN layer, forming a TiAlC layer on the second TiN layer, forming a barrier layer on the TiAlC layer, and forming a metal layer on the barrier layer, wherein the barrier layer has a thickness of 40 Å or greater.

According to still another aspect of the present inventive concept, there is provided a method for manufacturing a semiconductor device, the method including forming a gate dielectric layer on a substrate including a first region and a second region, forming a lower gate conductive layer on the second region, forming a capping conductive layer and an upper gate conductive layer on the first region and the second region, forming a barrier layer on the upper gate conductive layer, and forming a metal layer on the barrier layer, wherein the barrier layer has a thickness of 40 Å or greater.

### BRIEF DESCRIPTION OF THE DRAWINGS

The above and other features and advantages of the present inventive concept will become more apparent by describing in detail preferred embodiments thereof with reference to the attached drawings in which:

FIGS. 1 to 14 are cross-section views for reference in describing intermediate process steps of a method for manufacturing a semiconductor device according to an embodiment of the present inventive concept;

FIGS. 15 to 18 are cross-section views for reference in describing intermediate process steps of a method for manufacturing a semiconductor device according to another embodiment of the present inventive concept;

FIGS. 19 to 22 are cross-section views for reference in describing intermediate process steps of a method for manufacturing a semiconductor device according to still another embodiment of the present inventive concept;

FIG. 23 is a block diagram of a memory card including a semiconductor device manufactured by a semiconductor device manufacturing method according to some embodiments of the present inventive concept;

FIG. 24 is a block diagram of an information processing system using a semiconductor device manufactured by a semiconductor device manufacturing method according to some embodiments of the present inventive concept; and

FIG. 25 is a block diagram of an electronic system including a semiconductor device manufactured by a semiconductor device manufacturing method according to some embodiments of the present inventive concept.

### DETAILED DESCRIPTION OF THE EMBODIMENTS

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art, and the present inventive concept will only be defined by the appended claims. Like reference numerals refer to like elements throughout the specification.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

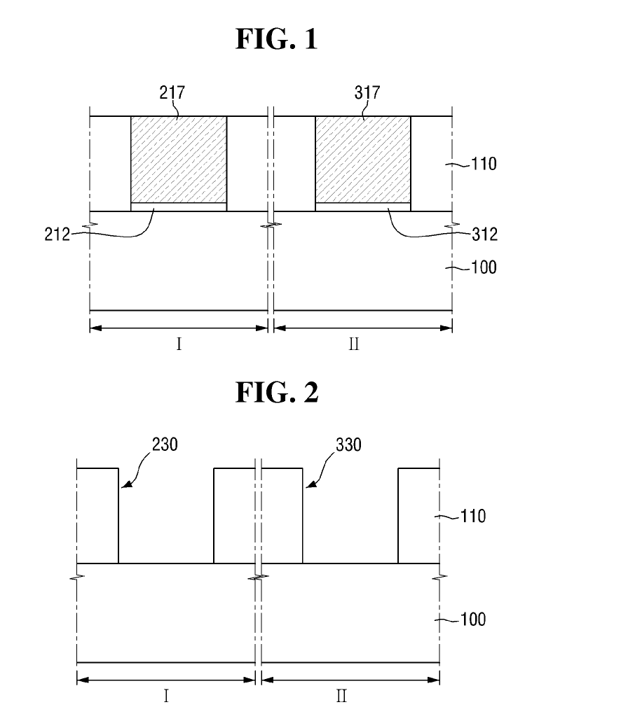

FIGS. 1 to 14 are cross-section views for reference in describing intermediate process steps of a method for manufacturing a semiconductor device according to an embodiment of the present inventive concept. For brevity, in the following description, source/drain regions formed in a substrate, an isolation layer, such as a shallow trench isolation (STI) layer, and a spacer formed on sidewalls of a sacrificial gate are not illustrated in FIGS. 1 to 14.

Referring to FIG. 1, the substrate 100 may have a first region I and a second region II. The first region I and the second region II may be separated from each other or may be connected to each other.

In some embodiments of the present inventive concept, the first region I may be an NMOS region and the second region II may be a PMOS region.

The substrate 100 may be, for example, bulk silicon or a silicon-on-insulator (SOI). Alternatively, the substrate 100 may be a silicon substrate, or a substrate made of other materials selected from the group consisting of, for example, germanium, silicon germanium, indium antimonide, lead telluride compound, indium arsenide, indium phosphide, gallium arsenide, and gallium antimonide. In addition, the substrate 100 may be an epitaxial layer formed on a base substrate.

The first dummy gate dielectric layer 212 and the second dummy gate dielectric layer 312 may include, for example, one of silicon oxide (SiO₂), silicon oxynitride (SiON) and a combination thereof. The first dummy gate dielectric layer 212 and the second dummy gate dielectric layer 312 may be formed by, for example, thermal treatment, chemical treatment, atomic layer deposition (ALD) or chemical vapor deposition (CVD).

The first dummy gate 217 and the second dummy gate 317 may include, for example, silicon (Si), specifically, poly Si, amorphous silicon (a-Si) and a combination thereof. The first dummy gate 217 and the second dummy gate 317 may both not be doped with impurity or may be doped with similar impurities. Alternatively, one of the first dummy gate 217 and the second dummy gate 317 may be doped and the other may not be doped. Alternatively, one of the first dummy gate 217 and the second dummy gate 317 may be doped with an n type material (e.g., arsenic, phosphorus, or the like) and the other may be doped with a p type material (e.g., boron, or the like).

Next, after the first dummy gate 217 and the second dummy gate 317 are formed, source/drain regions are formed at opposite sides of the first dummy gate 217 and the second dummy gate 317.

Next, an interlayer insulating layer 110 covering the first dummy gate 217 and the second dummy gate 317 is formed on the substrate 100. The interlayer insulating layer 110 may include, for example, at least one of a low k material, oxide, nitride and oxynitride. The low-k material may include flowable oxide (FOX), Tonen silazene (TOSZ), undoped silicate glass (USG), borosilica glass (BSG), phosphosilaca glass (PSG), borophosphor silica glass (BPSG), plasma enhanced tetraethyl orthosilicate (PETEOS), fluoride silicate glass (FSG), high density plasma (HDP) oxide, plasma enhanced oxide (PEOX), flowable CVD (FCVD), or combinations thereof, but not limited thereto.

Next, the interlayer insulating layer 110 is planarized to expose top surfaces of the first dummy gate 217 and the second dummy gate 317. For example, the planarizing may be performed by chemical mechanical polishing (CMP).

Referring to FIG. 2, the first dummy gate 217 and the second dummy gate 317 are removed. After the first dummy gate 217 and the second dummy gate 317 are removed, the first dummy gate dielectric layer 212 and the second dummy gate dielectric layer 312 are removed, thereby forming a first trench 230 and a second trench 330. A top surface of the substrate 100 may be exposed by the first trench 230 and the second trench 330.

In other words, the interlayer insulating layer 110 including the first trench 230 and the second trench 330 is formed on the substrate 100. The first trench 230 is formed on the first region I and the second trench 330 is formed on the second region II. In some embodiments of the present inventive concept, the first trench 230 is formed on the NMOS region and the second trench 330 is formed on the PMOS region.

The first dummy gate 217, the second dummy gate 317, the first dummy gate dielectric layer 212 and the second dummy gate dielectric layer 312 may be removed by wet etching or dry etching.

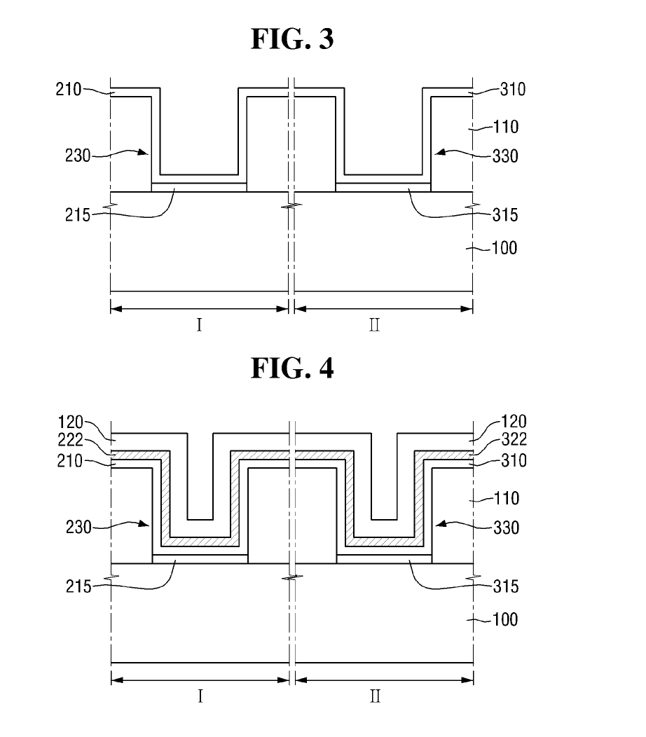

Referring to FIG. 3, a gate insulation layer is formed on the substrate 100. First, the first interface layer 215 and the second interface layer 315 are formed on bottom surfaces of the first trench 230 and the bottom surface of the second trench 330, respectively.

The first interface layer 215 and the second interface layer 315 may include silicon oxide. The first interface layer 215 and the second interface layer 315 may be formed using, for example, chemical oxidation, UV oxidation, or dual plasma oxidation.

A high-k gate dielectric layer 210 is conformally formed on the top surface of the interlayer insulating layer 110 and on the lateral surfaces and bottom surface of the first trench 230. In addition, along with the high-k dielectric layer 210, a high-k gate dielectric layer 310 is conformally formed on the top surface of the interlayer insulating layer 110 and on the lateral surfaces and bottom surface of the second trench 330. In detail, the high-k dielectric layers 210 and 310 are formed on the first interface layer 215 and the second interface layer 315, respectively.

In some embodiments of the present inventive concept, the high-k dielectric layers 210 and 310 may be simultaneously formed and may be formed using, for example, CVD or ALD. The high-k gate insulation layers 210 and 310 may include, for example, one or more selected from the group consisting of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but aspects of the present inventive concept are not limited thereto.

Referring to FIG. 4, conductive layers 222 and 322 are formed on the high-k gate insulation layers 210 and 310, respectively.

The conductive layers 222 and 322 may be conformally formed along the high-k gate insulation layers 210 and 310 using, for example, CVD or ALD. In some embodiments of the present inventive concept, the conductive layers 222 and 322 may be simultaneously formed and may include, for example, TiN layers.

Next, a capping layer 120 is formed on the conductive layers 222 and 322. After forming the capping layer 120, thermal treatment may be performed. The capping layer 120 may include, for example, one of poly silicon (poly Si), amorphous silicon (a-Si) and a combination thereof. When the thermal treatment is performed, the capping layer 120 may prevent thicknesses of the first interface layer 215 and the second interface layer 315 from increasing.

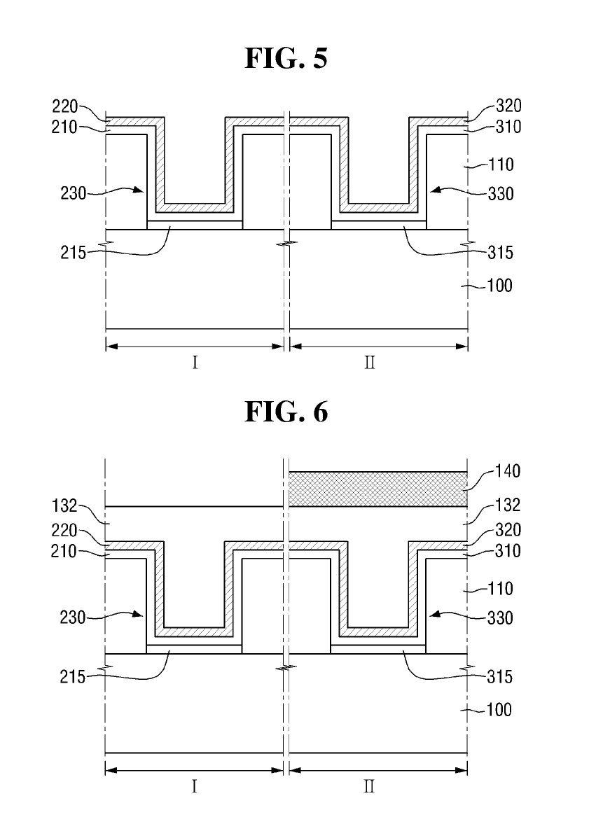

Referring to FIG. 5, the conductive layers 222 and 322 formed on the high-k gate insulation layers 210 and 310 and the capping layer 120 are removed to expose the high-k gate insulation layers 210 and 310. Next, a first lower gate conductive layer 220 is formed along the lateral surfaces and bottom surface of the first trench 230 and a second lower gate conductive layer 320 is formed along the lateral surfaces and bottom surface of the second trench 330. In this case, the lower gate conductive layers 220 and 320 may make direct contact with the high-k gate insulation layers 210 and 310.

The lower gate conductive layers 220 and 320 may be conformally formed along the high-k gate insulation layers 210 and 310 using, for example, CVD or ALD. In some embodiments of the present inventive concept, the lower gate conductive layers 220 and 320 may be simultaneously formed and may include, for example, TiN layers.

The first lower gate conductive layer 220 and the second lower gate conductive layer 320 may be p type work function control layers. For example, the first lower gate conductive layer 220 and the second lower gate conductive layer 320 may include, for example, TiN layers.

Referring to FIG. 6, a mask layer 132 filling the first trench 230 and the second trench 330 is formed. The mask layer 132 may also be formed on the top surface of the interlayer insulating layer 110.

The mask layer 132 may be a bottom anti-reflective coating (BARC) layer. In addition, the mask layer 132 may include a material having a good gap-filling characteristic so as to efficiently fill the first trench 230 and the second trench 330.

The mask layer 132 filling the first trench 230 and the second trench 330 is formed to make direct contact with the first lower gate conductive layer 220 and the second lower gate conductive layer 320.

Next, a photoresist film pattern 140 is formed on the mask layer 132. The photoresist film pattern 140 exposes the mask layer 132 formed on the first lower gate conductive layer 220, while covering the mask layer 132 formed on the second lower gate conductive layer 320. That is to say, the photoresist film pattern 140 exposes the first region I while covering the second region II. In addition, the photoresist film pattern 140 overlaps with the second lower gate conductive layer 320 while not overlapping with the first lower gate conductive layer 220.

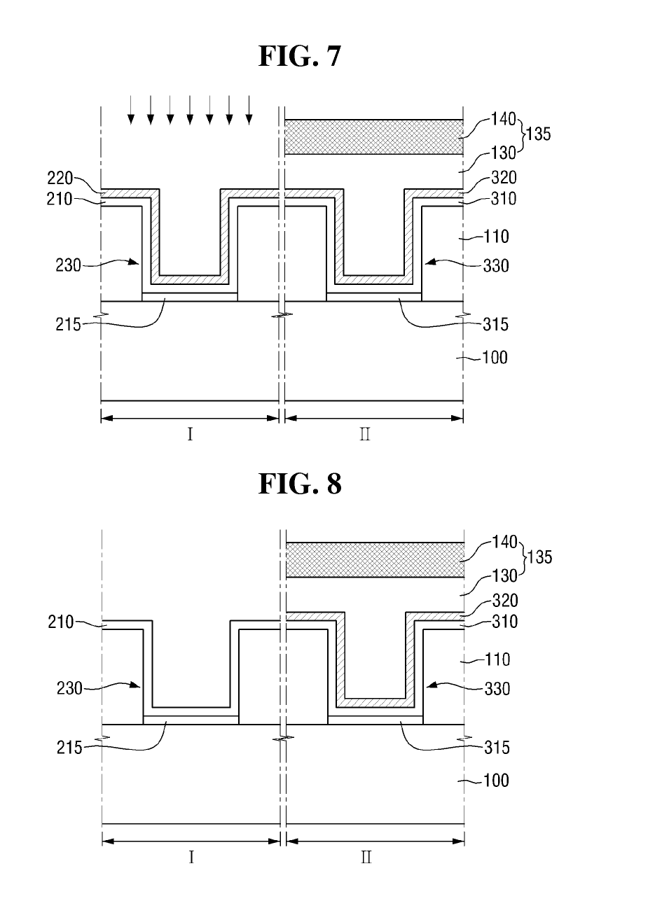

Referring to FIG. 7, the mask layer 132 filling the first trench 230 is removed using the photoresist film pattern 140 as a mask of an etching process. Through the etching process, a mask pattern 130 is formed on the second lower gate conductive layer 320. The mask pattern 130 fills the second trench 330 and may be a BARC pattern.

In other words, the mask layer 132 formed on the first lower gate conductive layer 220 is removed from the first region I, thereby forming the mask pattern 130. The mask layer 132 formed on the second lower gate conductive layer 320 and the photoresist film pattern 140 constitute a stacked layer to then be used as an etch mask in a subsequent process.

The mask layer 132 filling the first trench 230 and the first lower gate conductive layer 220 may be removed by dry etching. The dry etching may be performed by, for example, reactive ion etching (RIE). In an example of the dry etching for forming the mask pattern 130, the mask layer 132 filling the first trench 230 is etched using a mixed gas containing oxygen as an etch gas to then be removed. The mixed gas used as the etching gas may include chlorine in addition to oxygen. The mixed gas may further include helium.

In another example of the dry etching for forming the mask pattern 130, the mask layer 132 filling the first trench 230 is etched using a mixed gas containing nitrogen and hydrogen as an etch gas to then be removed.

Referring to FIG. 8, the first lower gate conductive layer 220 is removed using the mask pattern 130 as a mask. As the result of the removing of the first lower gate conductive layer 220, the high-k gate dielectric layer 210 may be exposed.

In detail, the first lower gate conductive layer 220 formed along the lateral surfaces and bottom surface of the first trench 230 is removed using a stacked layer 135 constituted by the mask pattern 130 and the photoresist film pattern 140 as an etch mask.

The first lower gate conductive layer 220 may be removed by, for example, wet etching. An etching solution used in wet etching may include, for example, hydrogen peroxide (H₂O₂), but aspects of the present inventive concept are not limited thereto. In the course of removing the first lower gate conductive layer 220, wet etching may be used to reduce damages applied to the high-k gate dielectric layer 210 to be exposed.

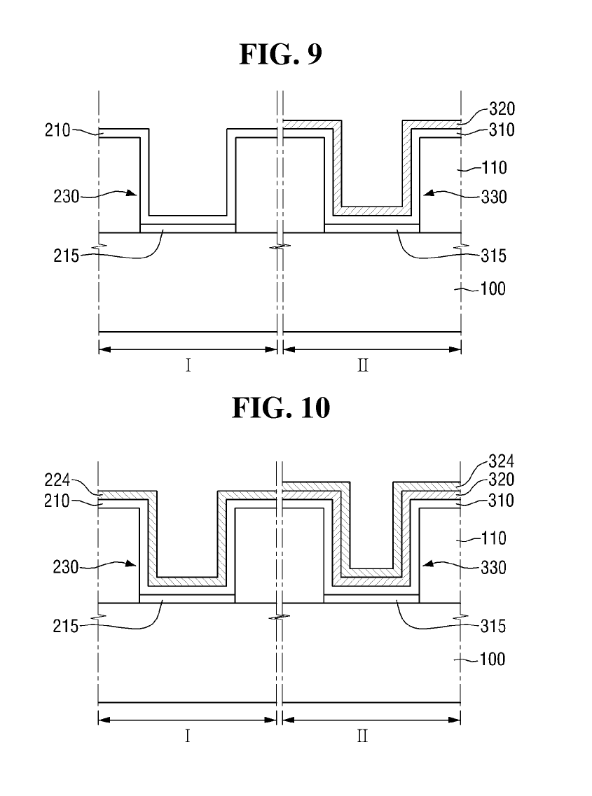

Referring to FIG. 9, the mask pattern 130 formed on the second lower gate conductive layer 320 and the photoresist film pattern 140 are removed. The stacked layer 135 constituted by the mask pattern 130 and the photoresist film pattern 140 is removed, thereby exposing the second lower gate conductive layer 320.

For example, the mask pattern 130 and the photoresist film pattern 140 may be ashed and stripped using a gas including hydrogen (H₂) and nitrogen (N₂).

The mask pattern 130 and the photoresist film pattern 140 are removed, thereby conformally forming the high-k gate insulation layer 310 and the second lower gate conductive layer 320 sequentially on the top surface of the interlayer insulating layer 110 formed on the second region II, on the lateral surfaces of the second trench 330 and on the second interface layer 315.

Unlike in a case where the second lower gate conductive layer 320 remains on the second region II, the high-k gate dielectric layer 210 is conformally formed on the top surface of the interlayer insulating layer 110 formed on the first region I, on the lateral surfaces of the first trench 230 and on the first interface layer 215.

Referring to FIG. 10, a first capping conductive layer 224 is formed along lateral surfaces and a bottom surface of the first trench 230 and a second capping conductive layer 324 is formed along lateral surfaces and a bottom surface of the second lower gate conductive layer 320. In this case, the first capping conductive layer 224 may make direct contact with the high-k gate dielectric layer 210 and the second capping conductive layer 324 may make direct contact with the second lower gate conductive layer 320.

The first capping conductive layer 224 and the second capping conductive layer 324 may be conformally formed along the high-k gate dielectric layer 210 and the second lower gate conductive layer 320 using, for example, CVD or ALD. In some embodiments of the present inventive concept, the first capping conductive layer 224 and the second capping conductive layer 324 may be simultaneously formed and may include, for example, TiN layers.

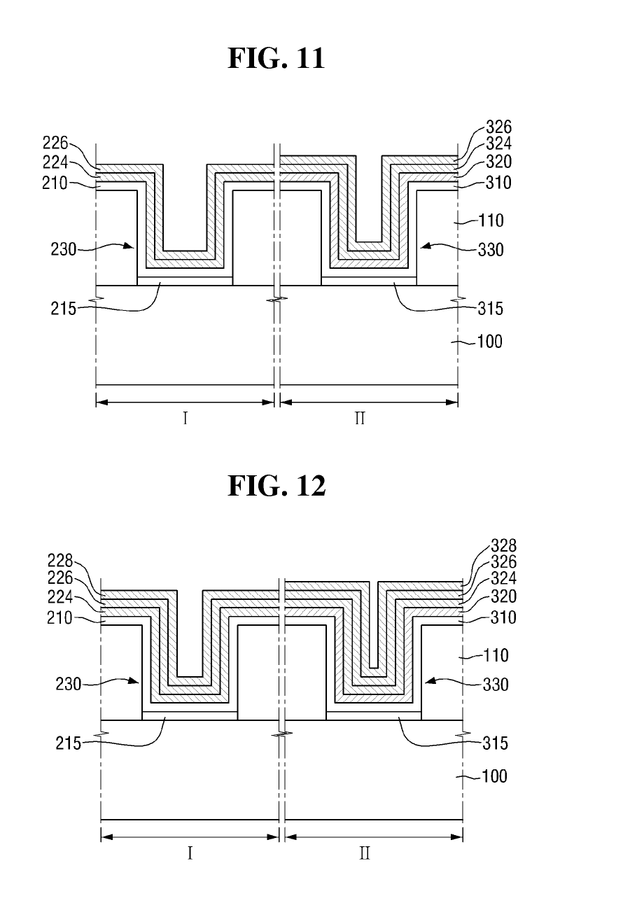

Referring to FIG. 11, a first upper gate conductive layer 226 and a second upper gate conductive layer 326 are formed on the first capping conductive layer 224 and the second capping conductive layer 324, respectively.

The first upper gate conductive layer 226 and the second upper gate conductive layer 326 may be n type work function control layers. The first upper gate conductive layer 226 and the second upper gate conductive layer 326 may be conformally formed along the first capping conductive layer 224 and the second capping conductive layer 324 using, for example, CVD or ALD. In some embodiments of the present inventive concept, the first upper gate conductive layer 226 and the second upper gate conductive layer 326 may be simultaneously formed and may include, for example, TiAlC layers.

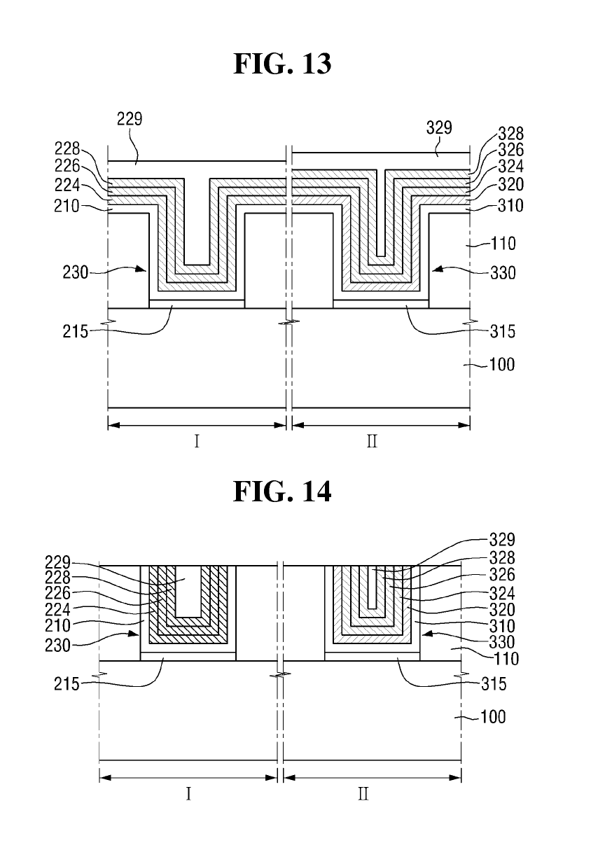

Referring to FIG. 12, a first barrier layer 228 and a second barrier layer 328 are formed on the first upper gate conductive layer 226 and the second upper gate conductive layer 326, respectively. The first barrier layer 228 and the second barrier layer 328 may serve as adhesion layers to the upper gate conductive layers 226 and 326 of a first metal layer 229 and a second metal layer 329 to be described later with reference to FIG. 13 while preventing tungsten hexafluoride (WF₆) from penetrating from the first metal layer 229 and the second metal layer 329 to the upper gate conductive layers 226 and 326.

The first barrier layer 228 and the second barrier layer 328 may be conformally formed along the first upper gate conductive layer 226 and the second upper gate conductive layer 326 using, for example, CVD or ALD. In some embodiments of the present inventive concept, the first barrier layer 228 and the second barrier layer 328 may be simultaneously formed and may include, for example, TiN layers.

In particular, in methods for manufacturing semiconductor devices according to various embodiments of the present inventive concept, the first barrier layer 228 and the second barrier layer 328 have a thickness of 40 Å or greater. In addition, in methods for manufacturing semiconductor devices according to various embodiments of the present inventive concept, the first barrier layer 228 and the second barrier layer 328 have a thickness of 100 Å or less. In methods for manufacturing semiconductor devices according to various embodiments of the present inventive concept, the thicknesses of the first barrier layer 228 and the second barrier layer 328 are made to be in a range between 40 Å and 100 Å, thereby, in 14 nm scale finFETs, suppressing cracks from being generated and reducing void failures.

Referring to FIG. 13, the first metal layer 229 and the second metal layer 329 are formed on the first barrier layer 228 and the second barrier layer 328, respectively. The first metal layer 229 and second metal layer 329 may be formed to fill the first trench 230 and the second trench 330, respectively. In some embodiments of the present inventive concept, the first metal layer 229 and the second metal layer 329 may be simultaneously formed and may include, for example, tungsten (W) layers.

Referring to FIG. 14, a first metal gate is formed to fill the first trench 230 and a second metal gate is formed to fill the second trench 330.

The first metal gate formed on the first trench 230 includes a first capping conductive layer 224, a first upper gate conductive layer 226, a first barrier layer 228 and a first metal layer 229. The second metal gate formed on the second trench 330 includes a second lower gate conductive layer 320, a second capping conductive layer 324, a second upper gate conductive layer 326, a second barrier layer 328 and a second metal layer 329.

Thereafter, metal layers 229 and 329, the barrier layers 228 and 328, the upper gate conductive layers 226 and 326, the capping conductive layers 224 and 324, the second lower gate conductive layer 320, and the high-k gate insulation layers 210 and 310 are planarized to expose a top surface of the interlayer insulating layer 110. The barrier layers 228 and 328, the upper gate conductive layers 226 and 326, the capping conductive layers 224 and 324 and the second lower gate conductive layer 320 may be conformally formed along lateral surfaces and bottom surfaces of the first trench 230 and the second trench 330.

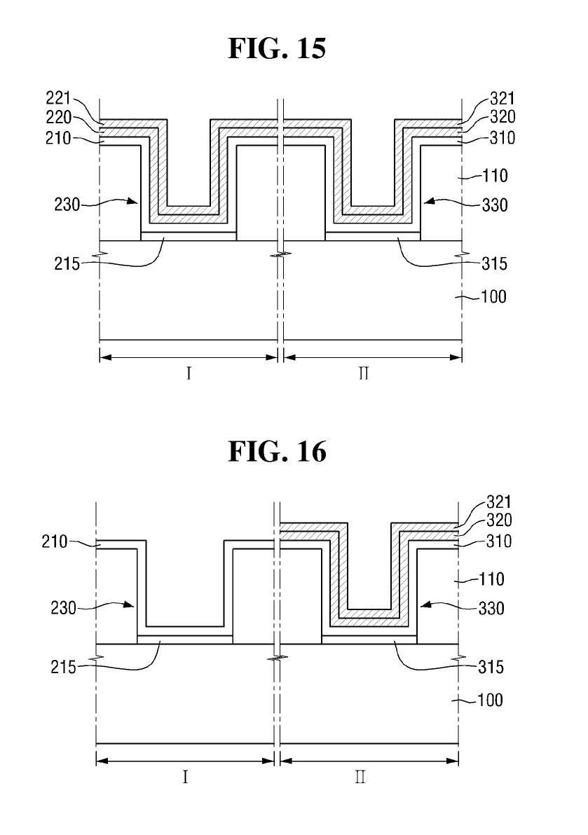

FIGS. 15 to 18 are cross-section views for reference in describing intermediate process steps of a method for manufacturing a semiconductor device according to another embodiment of the present inventive concept. For the sake of convenient explanation, the following description will focus on differences between the present embodiment and the previous embodiment shown in FIGS. 1 to 14.

Referring to FIG. 15 together with FIG. 5, the present inventive concept is different from the previous embodiment in that a lower gate conductive layer has a double layered structure consisting of a TiN layer and a TaN layer. For example, the lower gate conductive layers 220 and 221 of the first region I may include a first gate conductive layer 220 and a second gate conductive layer 221 formed on the first gate conductive layer 220, and the lower gate conductive layers 320 and 321 of the second region II may include a first gate conductive layer 320 and a second gate conductive layer 321 formed on the first gate conductive layer 320. Here, the first gate conductive layers 220 and 320 may include TiN layers and the second gate conductive layers 221 and 321 may include TaN layers.

Referring to FIG. 16 together with FIG. 9, the lower gate conductive layers 220 and 221 of the first region I are removed using the mask pattern 130 and the photoresist film pattern 140 and the lower gate conductive layers 320 and 321 remain in the second region II. The present embodiment is different from the previous embodiment in that the lower gate conductive layers 320 and 321 remain in the second region II, unlike in the previous embodiment in which only the second lower gate conductive layer 320 remains in the second region II.

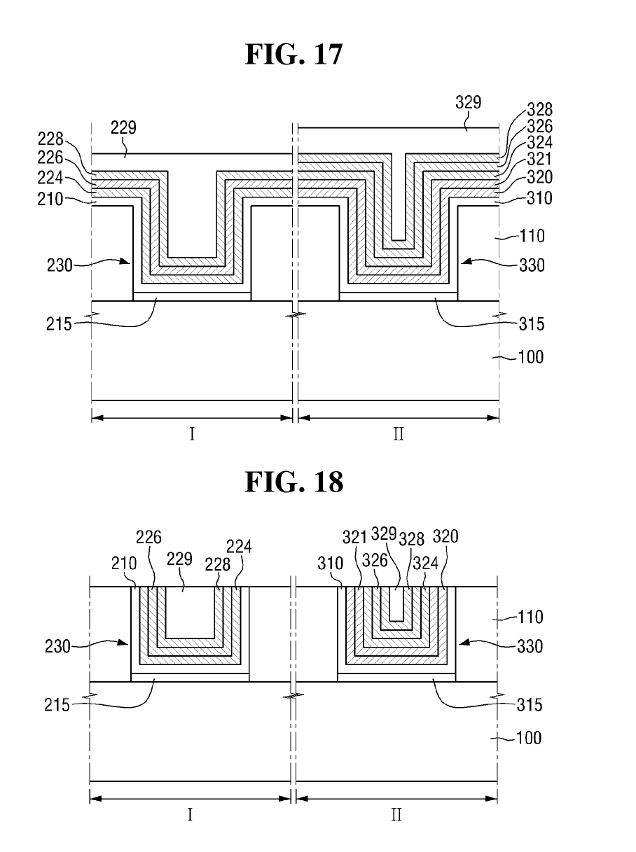

Referring to FIGS. 17 and 18, in a subsequent process, a first metal gate is formed to fill a first trench 230 and a second metal gate is formed to fill a second trench 330.

The first metal gate formed on the first trench 230 includes a first capping conductive layer 224, a first upper gate conductive layer 226, a first barrier layer 228 and a first metal layer 229 and the second metal gate formed on the second trench 330 includes a first gate conductive layer 320, a second gate conductive layer 321, a second capping conductive layer 324, a second upper gate conductive layer 326, a second barrier layer 328 and a second metal layer 329.

Like in the previous embodiment, the first barrier layer 228 and the second barrier layer 328 have a thickness of 40 Å or greater. In addition, in methods for manufacturing semiconductor devices according to various embodiments of the present inventive concept, the first barrier layer 228 and the second barrier layer 328 have a thickness of 100 Å or less. In methods for manufacturing semiconductor devices according to various embodiments of the present inventive concept, the thicknesses of the first barrier layer 228 and the second barrier layer 328 are made to be in a range between 40 Å and 100 Å, thereby, in 14 nm scale finFETs, suppressing cracks from being generated and reducing void failures.

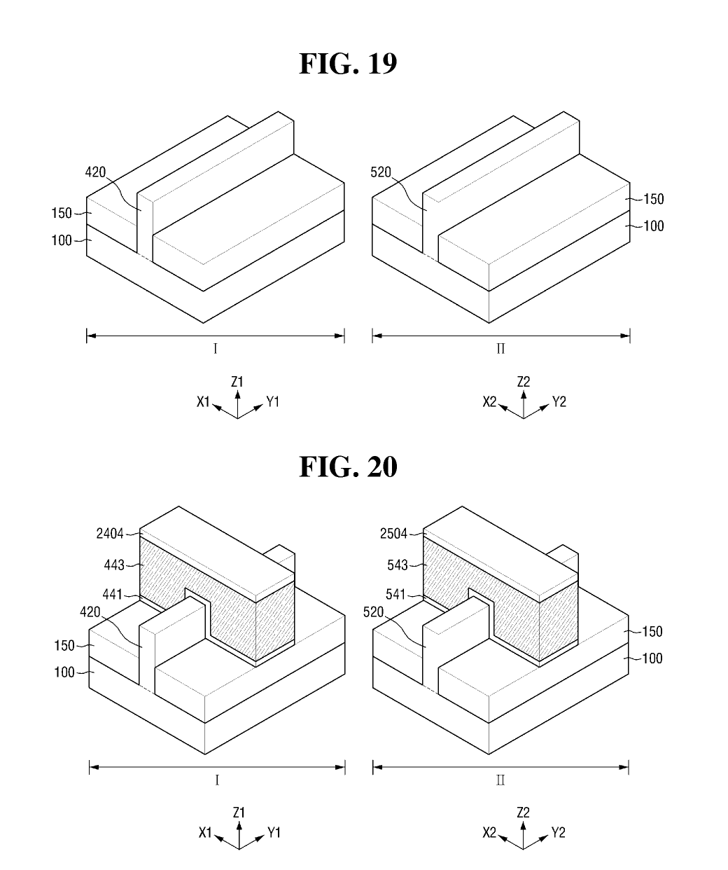

Next, a method for manufacturing a semiconductor device according to still another embodiment of the present inventive concept will be described with reference to FIGS. 19 to 22.

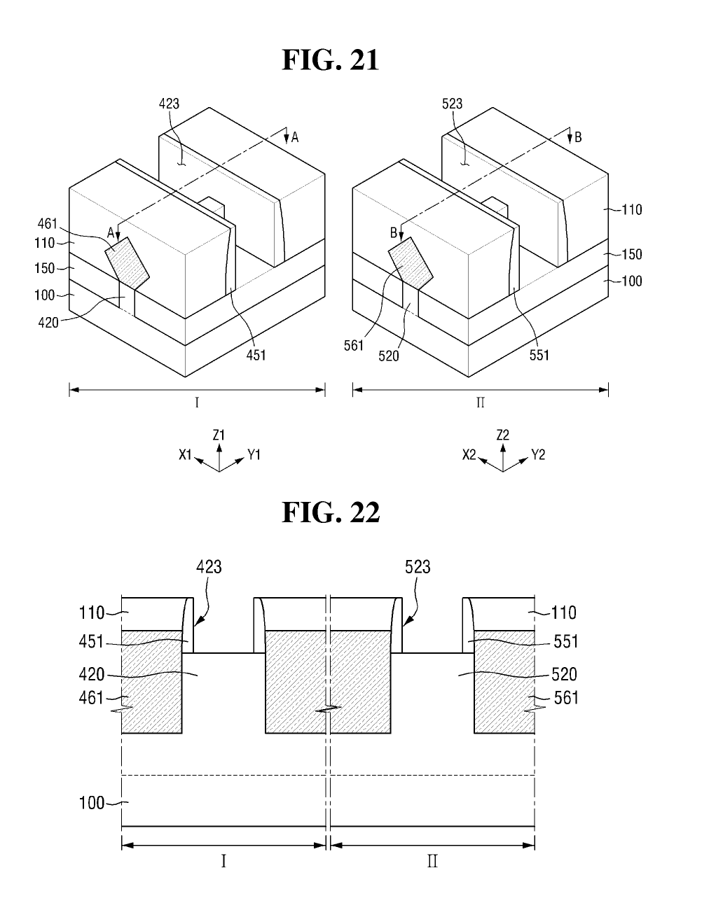

FIGS. 19 to 22 are cross-section views for reference in describing intermediate process steps of a method for manufacturing a semiconductor device according to still another embodiment of the present inventive concept. Specifically, FIG. 22 illustrates cross-sectional views taken along lines A-A and B-B of FIG. 21.

Referring to FIG. 19, a first fin type active pattern 420 and a second fin type active pattern 520 are formed on a substrate 100. The first fin type active pattern 420 is formed on a first region I and the second fin type active pattern 520 is formed on a second region II.

The first fin type active pattern 420 and the second fin type active pattern 520 may extend lengthwise along a second direction Y1-Y2. The first fin type active pattern 420 and the second fin type active pattern 520 may be portions of the substrate 100 and may include an epitaxial layer grown from the substrate 100. An isolation layer 150 may cover lateral surfaces of the first fin type active pattern 420 and the second fin type active pattern 520.

The first fin type active pattern 420 and the second fin type active pattern 520 may include, for example, an element semiconductor material, such as silicon or germanium. In addition, the first fin type active pattern 420 and the second fin type active pattern 520 may include a compound semiconductor, such as a group IV-IV compound semiconductor, or a group III-V compound semiconductor. In detail, the first fin type active pattern 420 and the second fin type active pattern 520 may include the group IV-IV compound semiconductor, including, for example, a binary compound or a ternary compound, including two or more group IV elements, such as carbon (C), silicon (Si), germanium (Ge), or tin (Sn), or a compound prepared by doping a group IV element into the binary or ternary compound.

In addition, the first fin type active pattern 420 and the second fin type active pattern 520 may include the group III-V compound semiconductor, including, for example, a binary compound, a ternary compound or a quaternary compound, prepared by combining at least one group III element of aluminum (Al), gallium (Ga) and indium (In) with at least one group V element of phosphorus (P), arsenic (As) and antimony (Sb).

Referring to FIG. 20, etching is performed using the first hard mask pattern 2404 and the second hard mask pattern 2504, thereby forming a third dummy gate 443 extending in the first direction X1 while crossing the first fin type active pattern 420 and a fourth dummy gate 543 crossing the second fin type active pattern 520 and extending in the first direction X2.

A third dummy gate dielectric layer 441 is formed between the first fin type active pattern 420 and the third dummy gate 443, and a fourth dummy gate dielectric layer 541 is formed between the second fin type active pattern 520 and the fourth dummy gate 543.

The third dummy gate dielectric layer 441 and the fourth dummy gate dielectric layer 541 may include, for example, one of silicon oxide (SiO₂), silicon oxynitride (SiON) and a combination thereof. The third dummy gate 443 and the fourth dummy gate 543 may include, for example, silicon (Si), specifically, poly Si, amorphous silicon (a-Si) and a combination thereof.

In the method for manufacturing a semiconductor device according to still another embodiment of the present inventive concept, the third dummy gate dielectric layer 441 and the fourth dummy gate dielectric layer 541 are formed, but aspects of the present inventive concept are not limited thereto. That is to say, like in the method for manufacturing a semiconductor device according to the second embodiment of the present inventive concept, an interface layer and third and fourth gate dielectric layers including high-k materials may also be formed under the third dummy gate 443 and the fourth dummy gate 543.

Referring to FIGS. 20 to 22, the third dummy gate 443 and the third dummy gate dielectric layer 441 are removed, thereby forming a third trench 423 crossing the first fin type active pattern 420 on the first fin type active pattern 420. In addition, the fourth dummy gate 543 and the fourth dummy gate dielectric layer 541 are removed, thereby forming a fourth trench 523 crossing the second fin type active pattern 520 on the second fin type active pattern 520.

In detail, a first spacer 451 and a second spacer 551 are formed on sidewalls of a third dummy gate 443 and a fourth dummy gate 543, respectively. When the first spacer 451 and the second spacer 551 are formed, portions of the first fin type active pattern 420 and the second fin type active pattern 520 not overlapping with the third dummy gate 443 and the fourth dummy gate 543 are removed, thereby forming recesses.

Next, a first source/drain 461 and a second source/drain 561 are formed on opposite sides of the third dummy gate 443 and the fourth dummy gate 543, respectively.

Next, an interlayer insulating layer 110, covering the first source/drain 461 and the second source/drain 561, is planarized. Through the planarizing, top surfaces of the third dummy gate 443 and the fourth dummy gate 543 are exposed.

Next, the third dummy gate 443, the third dummy gate dielectric layer 441, the fourth dummy gate 543 and the fourth dummy gate dielectric layer 541 are removed, thereby forming the third trench 423 in the first region I and the fourth trench 523 in the second region II.

Referring to FIG. 22, process steps subsequent to the forming of the third trench 423 and the fourth trench 523 are substantially the same as those shown in FIGS. 3 to 14, and repeated descriptions thereof will not be given or briefly given.

A first capping conductive layer 224, a first upper gate conductive layer 226, a first barrier layer 228 and a first metal layer 229 are formed in the third trench 423 of the first region I. In addition, a second lower gate conductive layer 320, a second capping conductive layer 324, a second upper gate conductive layer 326, a second barrier layer 328 and a second metal layer 329 are formed in the fourth trench 523 of the second region II.

A third metal gate, including the first capping conductive layer 224, the first upper gate conductive layer 226, the first barrier layer 228 and the first metal layer 229 of the first region I, fills the third trench 423 and surround a first fin type active pattern 420, and a fourth metal gate, including the second lower gate conductive layer 320, the second capping conductive layer 324, the second upper gate conductive layer 326, the second barrier layer 328 and the second metal layer 329 of the second region II, fills the fourth trench 523 and surrounds a second fin type active pattern 520

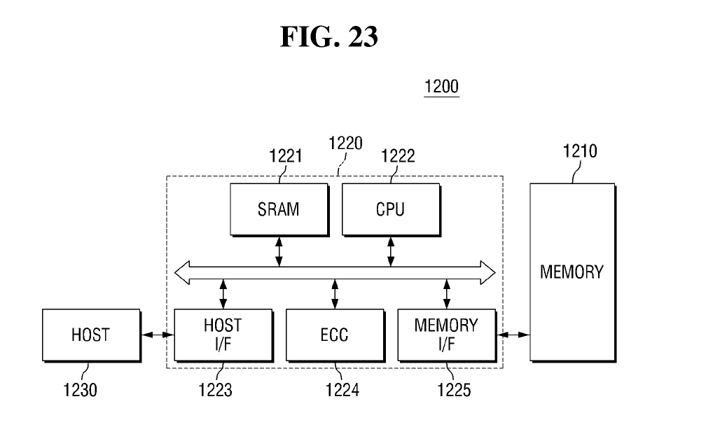

FIG. 23 is a block diagram of a memory card including a semiconductor device manufactured by a semiconductor device manufacturing method according to some embodiments of the present inventive concept.

Referring to FIG. 23, a memory 1210 including a semiconductor device according to various embodiments of the present inventive concept may be employed to the memory card 1200. The memory card 1200 may include a memory controller 1220 controlling data exchange between a host 1230 and a memory 1210. An SRAM 1221 may be used as a working memory of a central processing unit 1222. A host interface 1223 may include a protocol for exchanging data to allow the host 1230 to access the memory card 1200. An error correction code 1224 may be used to detect and correct an error of data read from the memory 1210. A memory interface 1225 may interface with the memory 1210. The central processing unit 1222 may perform the overall control operation associated with the data exchange of the memory controller 1220.

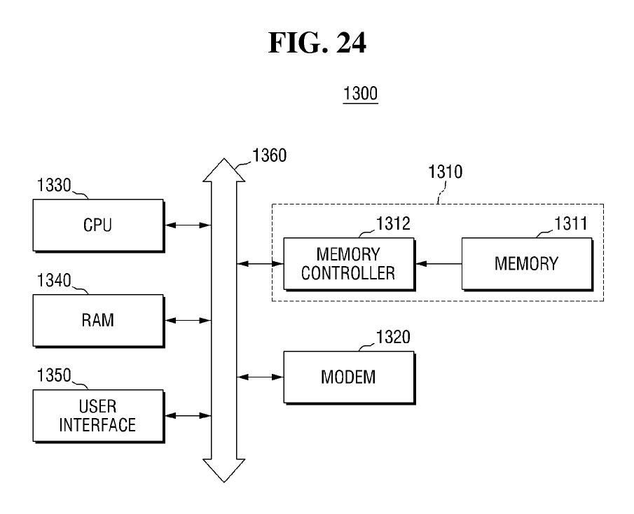

FIG. 24 is a block diagram of an information processing system using a semiconductor device manufactured by a semiconductor device manufacturing method according to some embodiments of the present inventive concept.

Referring to FIG. 24, the information processing system 1300 may include a memory system 1310 including a semiconductor device according to various embodiments of the present inventive concept. The information processing system 1300 may include a memory system 1310, a modem 1320, a central processing unit 1330, an RAM 1340 and a user interface 1350, which are electrically connected to a system bus 1360. The memory system 1310 may include a memory 1311 and a memory controller 1312 and may have substantially the same configuration as the memory card 1200 shown in FIG. 23. Data processed by the central processing unit 1330 or externally applied data may be stored in the memory system 1310. The information processing system 1300 may be applied to a memory card, a solid state disk (SSD), a camera image sensor and other various chip sets. For example, the memory system 1310 may be configured to employ the SSD. In this case, the information processing system 1300 may process a large amount of data in a stable, reliable manner.

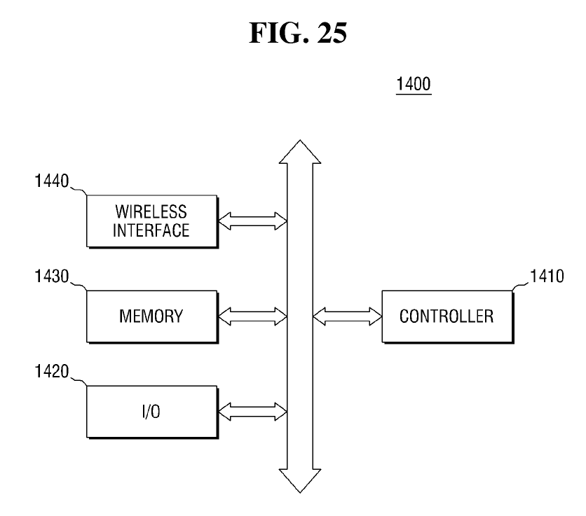

FIG. 25 is a block diagram of an electronic system including a semiconductor device manufactured by a semiconductor device manufacturing method according to some embodiments of the present inventive concept.

Referring to FIG. 25, the electronic device 1400 may include a semiconductor device according to various embodiments of the present inventive concept. The electronic device 1400 may be applied to a wireless communication device (for example, a personal digital assistant (PDA), a notebook computer, a portable computer, a web tablet, a wireless phone, and/or a wireless digital music player) or any type of electronic device capable of transmitting and/or receiving information in a wireless environment.

The electronic device 1400 may include a controller 1410, an input/output device (I/O) 1420, a memory 1430, and a wireless interface 1440. Here, the memory 1430 may include a semiconductor device according to various embodiments of the present inventive concept. The controller 1410 may include a microprocessor, a digital signal processor, and a processor capable of performing functions similar to these components. The memory 1430 may be used to store commands processed by the controller 1410 (or user data). The wireless interface 1440 may be used to exchange data through a wireless data network. The wireless interface 1440 may include an antenna or a wired/wireless transceiver. For example, the electronic device 1400 may use a third generation communication system protocol, such as CDMA, GSM, NADC, E-TDMA, WCDMA, CDMA2000, or the like.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed is:

1. A method of manufacturing a semiconductor device, the method comprising:
forming an interlayer insulating layer including a first trench and a second trench on a substrate;
forming a lower gate conductive layer along lateral surfaces and a bottom surface of the second trench;
forming a first capping conductive layer along lateral surfaces and a bottom surface of the first trench and forming a second capping conductive layer on the lower gate conductive layer;
forming a first upper gate conductive layer on the first capping conductive layer and forming a second upper gate conductive layer on the second capping conductive layer;
forming a first barrier layer on the first upper gate conductive layer and forming a second barrier layer on the second upper gate conductive layer; and
forming a first metal layer on the first barrier layer and forming a second metal layer on the second barrier layer,
wherein the first barrier layer and the second barrier layer have a thickness of 40 Å or greater.

2. The method of claim 1, wherein the first barrier layer and the second barrier layer have a thickness of 100 Å or less.

3. The method of claim 1, wherein the forming of the lower gate conductive layer along the lateral surfaces and the bottom surface of the second trench comprises:
forming a first lower gate conductive layer along the lateral surfaces and the bottom surface of the first trench;
forming a second lower gate conductive layer along the lateral surfaces and the bottom surface of the second trench;
forming a mask pattern filling the second trench on the second lower gate conductive layer as a bottom anti-reflective coating (BARC) layer; and
removing the first lower gate conductive layer using the mask pattern,
wherein the lower gate conductive layer is the second lower gate conductive layer.

4. The method of claim 1, wherein the lower gate conductive layer includes a TiN layer.

5. The method of claim 1, wherein the lower gate conductive layer includes a first gate conductive layer and a second gate conductive layer formed on the first gate conductive layer, the first gate conductive layer includes a TiN layer, and the second gate conductive layer includes a TaN layer.

6. The method of claim 1, wherein the first barrier layer and the second barrier layer include TiN layers.

7. The method of claim 1, wherein the first metal layer and the second metal layer include tungsten (W) layers.

8. The method of claim 1, wherein the forming of the first trench and the second trench comprises:
forming a first dummy gate and a second dummy gate on the substrate, the first dummy gate and the second dummy gate being formed on a first and a second region of the substrate, respectively;
forming the interlayer insulating layer covering the first dummy gate and the second dummy gate on the substrate;
planarizing the interlayer insulating layer to expose the first dummy gate and the second dummy gate; and
removing the first dummy gate and the second dummy gate.

9. The method of claim 1, wherein the first trench is formed in an NMOS region and the second trench is formed in a PMOS region.

10. A method of manufacturing a semiconductor device, the method comprising:
forming a first fin type active pattern and a second fin type active pattern on a substrate;
forming a first trench crossing the first fin type active pattern on the first fin type active pattern and forming a second trench crossing the second fin type active pattern on the second fin type active pattern;
forming a first TiN layer along lateral surfaces and a bottom surface of the second trench;
forming a second TiN layer along lateral surfaces and a bottom surface of the first trench and on the first TiN layer;
forming a TiAlC layer on the second TiN layer;
forming a barrier layer on the TiAlC layer; and
forming a metal layer on the barrier layer,
wherein the barrier layer has a thickness of 40 Å or greater.

11. The method of claim 10, wherein the barrier layer has a thickness of 100 Å or less.

12. The method of claim 10, further comprising forming a TaN layer on the first TiN layer, wherein the forming of the second TiN layer on the first TiN layer comprises forming the second TiN layer on the TaN layer.

13. The method of claim 10, wherein the barrier layer includes a TiN layer.

14. The method of claim 10, wherein the metal layer includes a tungsten (W) layer.

15. A method for manufacturing a semiconductor device, the method comprising:
forming a gate dielectric layer on a substrate including a first region and a second region;
forming a lower gate conductive layer on the second region;
forming a capping conductive layer and an upper gate conductive layer on the first and second regions;
forming a barrier layer on the upper gate conductive layer; and
forming a metal layer on the barrier layer,
wherein the barrier layer has a thickness of 40 Å or greater.

16. The method of claim 15, wherein the barrier layer has a thickness of 100 Å or less.

17. The method of claim 15, wherein the forming of the gate dielectric layer on the substrate including the first region and the second region comprises:
forming an interface layer on the substrate; and
forming a high-k gate dielectric layer on the interface layer,
wherein the capping conductive layer of the first region and the lower gate conductive layer of the second region directly contact to the high-k gate dielectric layer.

18. The method of claim 15, wherein the forming of the gate dielectric layer on the substrate including the first region and the second region comprises:
forming a first trench on the first region and forming a second trench on the second region; and
forming the gate dielectric layer along lateral surfaces and bottom surfaces of the first and second trenches.

19. The method of claim 15, wherein the capping conductive layer and the barrier layer include TiN layers.

20. The method of claim 15, wherein the metal layer includes a tungsten (W) layer.
